(19) United States
(12) Patent Application Publication
(10) Pub. No.: US 2007/0001307 A1
(43) Pub. Date: Jan. 4, 2007

(54) Semiconductor device advantageous in improving water resistance and oxidation resistance

(75) Inventors: Takamasa Usui, Tokyo (JP); Hayato Nasu, Yokohama-shi (JP); Hideki Shibata, Yokohama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/440,453

(22) Filed: May 25, 2006

(30) Foreign Application Priority Data
Jul. 1, 2005 (JP) 2005-193965

(51) Int. Cl. H01L 23/52

(52) U.S. Cl. 257/758; 257/774; 257/E23.145

(57) ABSTRACT

A semiconductor device includes a guard ring formed in an inter-level insulating film on a semiconductor substrate to surround an element forming region on the semiconductor substrate and containing Cu as a main component. And the device further includes a first barrier film formed on an interface between the inter-level insulating film and the guard ring and containing a compound of a preset metal element and a constituent element of the inter-level insulating film as a main component.

### CROSS-REFERENCE TO RELATED APPLICATIONS

This application is based upon and claims the benefit of priority from prior Japanese Patent Application No. 2005-193965, filed Jul. 1, 2005, the entire contents of which are incorporated herein by reference.

### BACKGROUND OF THE INVENTION

1. Field of the Invention

This invention relates to a semiconductor device and is applied to, for example, a guard ring in a multilayered wiring of an LSI (Large Scale Integrated Circuit), the side surface and passivation structure outside the guard ring, a fuse melting window in the wiring and the fuse structure, the structure of a bonding pad portion and the like.

2. Description of the Related Art

Conventionally, in the multilayered wiring of an LSI, in order to protect the wirings, connection holes, transistors and the like in a semiconductor chip from water and oxidizing gas from the exterior, plural-layered guard rings (for example, nine-layered guard rings) are provided on the peripheral portion of the chip.

Recently, particularly, in the multilayered wiring, an LSI using an inter-level insulating film (so-called low-k film) with a low dielectric constant is often used from the viewpoint of the performance (for example, Jpn. Pat. Appln. KOKAI Publication No. 2004-172169). However, the inter-level insulating film with a low dielectric constant generally has the property of permitting oxidizing gas such as O (oxygen) and water to easily pass therethrough in addition to a tendency to contain a large amount of water. Due to the property of permitting the oxidizing gas and the like to easily pass through the inter-level insulating film, water and oxidizing gas are passed through to oxidize the metal (for example, copper (Cu)) of the guard ring and the barrier metal (for example, tantalum (Ta)). Therefore, even if the guard ring is formed in a multilayered form, all of the films are oxidized. Finally, the wirings and connection holes in the chip are oxidized and corroded and the performance of the LSI is deteriorated.

Further, in the present LSI, penetration of water and oxidizing gas as described above is prevented by generally forming a guard ring on the side surface of the chip and a passivation film on the upper surface. As the passivation film formed on the upper surface, an SiN film (silicon nitride film) is often used. However, in order to prevent penetration of the water and oxidizing gas by use of the SiN film, it is necessary to set the film thickness of the SiN film to such a large value as 600 nm or more. As a result, the miniaturization of the device is prevented and the manufacturing cost will rise. In addition, if the film thickness of the passivation film is made large, the thickness of a film on the side wall portion becomes small in the wiring having a large step difference. Therefore, it becomes necessary to further increase the film thickness, thereby making it further difficult to miniaturize the device.

Further, in a wiring fuse of the LSI, particularly, when an inter-level insulating film with a small dielectric constant is used, the fuse itself tends to be oxidized and corroded starting from the side wall and bottom portion of the window in which a fuse window before blowing is formed. Further, for example, in the case of Cu wiring, the Cu wiring is exposed after the fuse is blown and the fuse itself is instantly oxidized and corroded.

Further, when the Cu wiring is used on the top layer in the LSI wiring, a portion which is not connected to a wire after wire bonding and in which the Cu surface is exposed is oxidized since the Cu itself has no oxidation resistance. In order to solve the above problem, it is general to further form a single-layered aluminum layer. As a result, the manufacturing cost becomes extremely high.

### BRIEF SUMMARY OF THE INVENTION

A semiconductor device according to one aspect of the present invention comprises a guard ring formed in an inter-level insulating film on a semiconductor substrate to surround an element forming region on the semiconductor substrate and containing Cu as a main component, and a first barrier film formed on an interface between the inter-level insulating film and the guard ring and containing a compound of a preset metal element and a constituent element of the inter-level insulating film as a main component.

A semiconductor device according to another aspect of the present invention comprises a fuse formed in an inter-level insulating film on a semiconductor substrate and containing Cu as a main component, a fuse melting window formed in a portion of the inter-level insulating film which lies on the fuse to melt the fuse, and a first barrier film formed on the side wall and bottom surface of the fuse melting window and containing a compound of a preset metal element and a constituent element of the inter-level insulating film as a main component.

A semiconductor device according to still another aspect of the present invention comprises a power supply layer formed in an inter-level insulating film on a semiconductor substrate and containing Cu as a main component, a bonding wire formed on the power supply layer, an insulating film formed to cover the power supply layer and bonding wire, and a first barrier film formed on an interface between the insulating film and the power supply layer and containing a compound of a preset metal element and a constituent element of the insulating film as a main component.

### BRIEF DESCRIPTION OF THE SEVERAL VIEWS OF THE DRAWING

FIG. 1 is a cross sectional view showing a semiconductor device according to a first embodiment of this invention;

FIG. 2 is a view showing a microphotograph of a cross sectional TEM image of a portion near a region 20 shown in FIG. 1;

FIG. 3 is a cross sectional view showing one manufacturing step of the semiconductor device according to the first embodiment of this invention;

FIG. 4 is a cross sectional view showing one manufacturing step of the semiconductor device according to the first embodiment of this invention;

FIG. 5 is a cross sectional view showing one manufacturing step of the semiconductor device according to the first embodiment of this invention;

FIG. 6 is a cross sectional view showing one manufacturing step of the semiconductor device according to the first embodiment of this invention;

FIG. 7 is a cross sectional view showing a semiconductor device according to a second embodiment of this invention;

FIG. 8 is a cross sectional view showing one manufacturing step of the semiconductor device according to the second embodiment of this invention;

FIG. 9 is a cross sectional view showing one manufacturing step of the semiconductor device according to the second embodiment of this invention;

FIG. 10 is a cross sectional view showing one manufacturing step of the semiconductor device according to the second embodiment of this invention;

FIG. 11 is a cross sectional view showing a semiconductor device according to a modification 1 of the second embodiment of this invention;

FIG. 12 is a cross sectional view showing a semiconductor device according to a modification 2 of the second embodiment of this invention;

FIG. 13 is a cross sectional view showing a semiconductor device according to a modification 3 of the second embodiment of this invention;

FIG. 14 is a cross sectional view showing a semiconductor device according to a third embodiment of this invention;

FIG. 15 is a cross sectional view showing a semiconductor device according to a modification 4 of the third embodiment of this invention;

FIG. 16 is a cross sectional view showing a semiconductor device according to a fourth embodiment of this invention;

FIG. 17 is a cross sectional view showing one manufacturing step of the semiconductor device according to the fourth embodiment of this invention;

FIG. 18 is a cross sectional view showing one manufacturing step of the semiconductor device according to the fourth embodiment of this invention;

FIG. 19 is a cross sectional view showing a semiconductor device according to a fifth embodiment of this invention;

FIG. 20 is a cross sectional view showing one manufacturing step of the semiconductor device according to the fifth embodiment of this invention;

FIG. 21 is a cross sectional view showing one manufacturing step of the semiconductor device according to the fifth embodiment of this invention;

FIG. 22 is a cross sectional view showing one manufacturing step of the semiconductor device according to the fifth embodiment of this invention;

FIG. 23 is a cross sectional view showing a semiconductor device according to a sixth embodiment of this invention;

FIG. 24 is a cross sectional view showing one manufacturing step of the semiconductor device according to the sixth embodiment of this invention;

FIG. 25 is a cross sectional view showing one manufacturing step of the semiconductor device according to the sixth embodiment of this invention;

FIG. 26 is a cross sectional view showing one manufacturing step of the semiconductor device according to the sixth embodiment of this invention;

FIG. 27 is a cross sectional view showing one manufacturing step of the semiconductor device according to the sixth embodiment of this invention; and

FIG. 28 is a cross sectional view showing one manufacturing step of the semiconductor device according to the sixth embodiment of this invention.

### DETAILED DESCRIPTION OF THE INVENTION

There will now be described embodiments of this invention with reference to the accompanying drawings. In this explanation, common reference symbols are attached to like portions throughout the drawings.

### FIRST EMBODIMENT

### Guard Ring

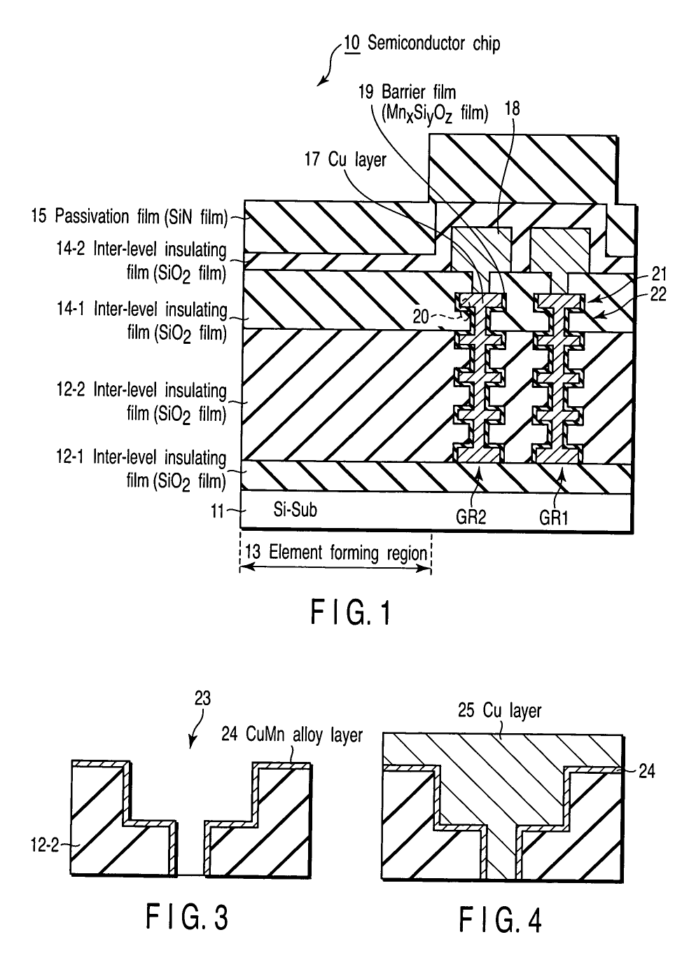

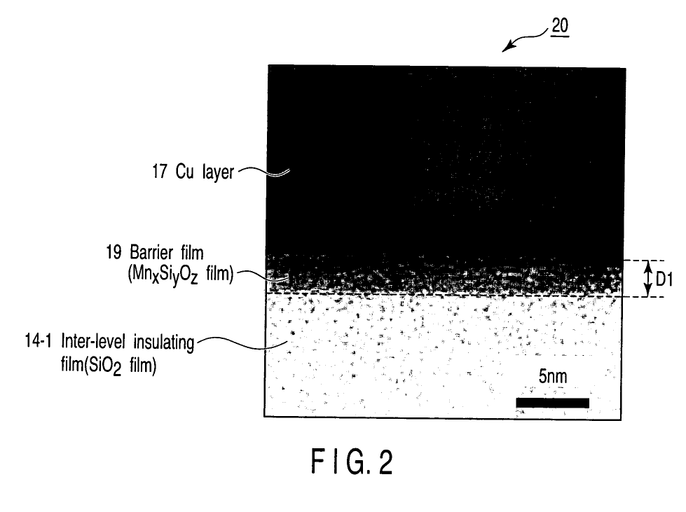

First, a semiconductor device according to a first embodiment of this invention is explained with reference to FIGS. 1 and 2. FIG. 1 is a cross sectional view schematically showing the semiconductor device according to the first embodiment. FIG. 2 is a view showing a microphotograph of a cross sectional TEM image of a portion near a region 20 shown in FIG. 1. The embodiment relates to guard rings formed on the peripheral portion of a semiconductor chip to protect wirings, connection holes, transistors and the like in the semiconductor chip from external water and oxidizing gas and a manufacturing method thereof.

As shown in FIG. 1, a semiconductor chip 10 is formed on a silicon substrate 11. A passivation film (SiN film) 15 is formed on an inter-level insulating film 14-2 to cover the semiconductor chip 10. Element structures such as transistors are generally formed in an inter-level insulating film 12-1 in an element forming region 13 on the substrate 11, but they are omitted here for simplicity.

Guard rings GR1, GR2 containing Cu as a main component (that is, 50% or more) are formed in the inter-level insulating films 12-1, 12-2, 14-1 on the substrate 11 to surround the element forming region 13. The guard rings GR1, GR2 each include a wiring layer 21 formed in the inter-level insulating films 12-1, 12-2, 14-1 and a contact plug 22 linked with and electrically connected to the wiring layer 21. For example, the inter-level insulating films 12-1, 12-2, 14-1, 14-2 are formed of an SiO₂ film (silicon oxide film), SiOC film (low dielectric constant insulating film) or porous SiOC film. As shown in FIG. 1, the guard rings GR1, GR2 are formed by use of a multilayered wiring structure.

Barrier films 19 containing a compound of the constituent element (for example, Si, O or the like) of the inter-level insulating films 12-1, 12-2, 14-1 and a preset metal element (for example, Mn) are formed on the interfaces between the inter-level insulating films 12-1, 12-2, 14-1 and the guard rings GR1, GR2.

In this example, the barrier film 19 is formed of an MnₓSi_{y}O_{z} (manganese silicon oxide) film. The composition of the MnₓSi_{y}O_{z} film is specifically expressed by 1:1:3 to 1:3:5 as x:y:z of MnₓSi_{y}O_{z}.

As shown in FIG. 2, the barrier film 19 is a thin and uniform MnₓSi_{y}O_{z} film and the film thickness D1 thereof is approximately 2 nm to 3 nm. The barrier film 19 also functions as a diffusion barrier film used to prevent diffusion of Cu elements in a Cu layer 17.

The barrier film 19 contains a compound of the constituent element of the inter-level insulating films 12-2, 14-1 and a preset metal element a as a main component and is formed in a self-alignment fashion.

The preset metal element a is not limited to Mn as in the present embodiment and may include at least one element selected from a group consisting of Nb, Zr, Cr, V, Y, Tc and Re.

The inter-level insulating films 12-1, 12-2, 14-1, 14-2 can contain O and at least one element selected from a group consisting of Si, C and F. As a specific material, for example, SiO₂, SiOₓC_{y}, SiOₓC_{y}H_{z}, SiOₓF_{y} and the like can be provided.

Further, the barrier film 19 can contain a material selected from a group consisting of αₓO_{y}, αₓSi_{y}O_{z} αₓC_{y}O_{z} and αₓF_{y}O_{z} as a main component. In this case, a indicates the preset metal element α.

As described above, since the barrier film (MnₓSi_{y}O_{z} film) 19 is an oxide, it is not oxidized any more. Therefore, the resistance to oxidation of the guard rings GR1, GR2 can be improved and the wirings in the semiconductor chip 10 can be protected from oxidation. Further, since the barrier film is a reaction-formed film which is no more oxidized and is continuously and densely formed, it does not permit water to pass therethrough. Therefore, the water resistance of the guard rings GR1, GR2 can be enhanced.

<Manufacturing Method>

Next, a manufacturing method of the semiconductor device according to the present embodiment is explained with reference to FIGS. 3 to 6. In this explanation, part of the guard ring in the inter-level insulating film 12-2 is explained as an example for simplicity.

First, as shown in FIG. 3, a groove 23 having a wiring groove and a connection hole is formed in the inter-level insulating film 12-2 by use of an anisotropic etching process such as an RIE (Reactive Ion Etching) process, for example. Then, a CuMn layer 24 is deposited on the inter-level insulating film 12-2 and in the groove 23 by use of a sputtering method associated with a Cu wiring process and a Cu wiring. When the CuMn layer 24 is formed, the concentration of Mn elements of a CuMn target for sputtering is approximately 0.05 to 10 atomic %, for example.

Then, as shown in FIG. 4, a Cu layer 25 is deposited on the CuMn layer 24 by use of a plating method.

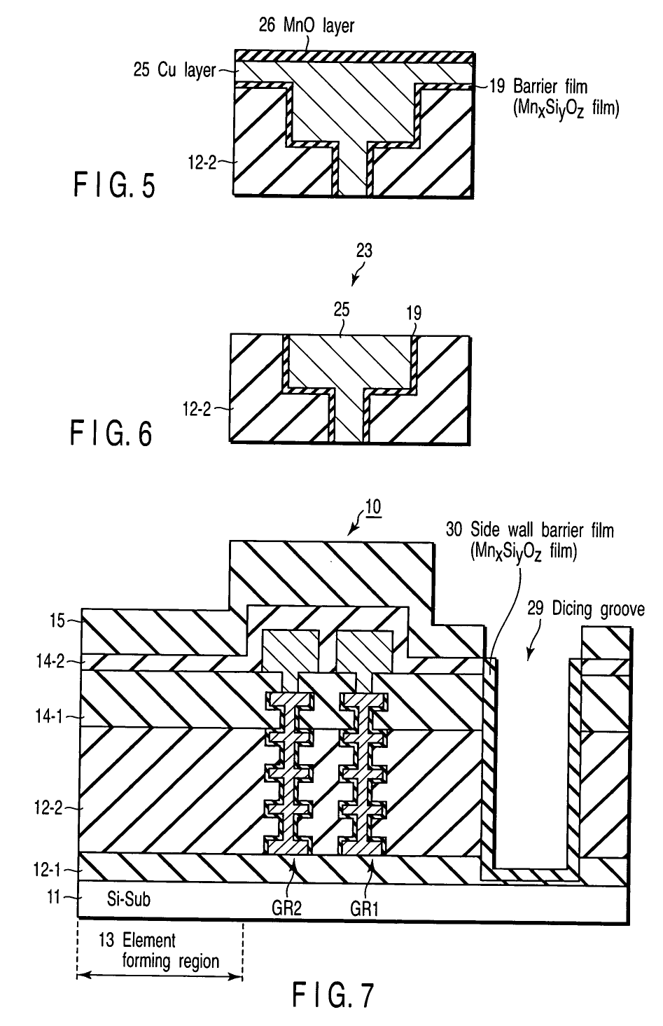

After this, as shown in FIG. 5, for example, the heat treatment (annealing process) is performed for 30 min to 60 min at temperatures of 200° C. to 600° C. while the CuMn alloy layer 24 is kept set in contact with the insulating layer 12-2. By the heat treatment, Mn elements in the CuMn alloy layer 24 are diffused to react with Si elements and O elements in the insulating layer 12-2 to form a uniform MnₓSi_{y}O_{z} film (barrier film) 19 with extremely thin film thickness (2 nm to 3 nm) on the interface in a self-alignment fashion. Further, in the above process, surplus Mn on the surface of the Cu layer 25 which faces the insulating film 12-2 moves to the upper portion and reacts with oxygen in the annealing atmosphere to form an MnO layer 26 on the surface.

It is confirmed that the film thickness of the MnₓSi_{y}O_{z} film (barrier film) 19 is kept constant irrespective of the Mn concentration in the CuMn alloy layer 24. This is considered so because Mn in the CuMn alloy layer 24 cannot take in any more oxygen (O) in the inter-level insulating film 12-2 and the reaction process is stopped if the MnₓSi_{y}O_{z} film 19 is uniformly formed.

Further, it is possible to precipitate almost all of the Mn elements in the CuMn alloy layer 24 by suitably selecting the concentration of the Mn elements and time and reaction condition of the heat treatment process. In this case, the guard rings GR1, GR2 can be formed of pure Cu.

Next, as shown in FIG. 6, for example, the Cu layer 25 is polished and made flat to the surface of the inter-level insulating film 12-2 by using a CMP (Chemical Mechanical Polishing) method. Thus, the MnO layer 26, a surplus portion of the Cu layer 25 and a portion of the barrier film 19 which lies on the inter-level insulating film 12-2 are removed.

By repeatedly performing the above manufacturing process, the semiconductor device shown in FIGS. 1 and 2 is formed. Thus, the guard rings GR1, GR2 according to the present embodiment can be formed by the same manufacturing process as that for forming the multilayered wiring structure.

As described above, according to the configuration and manufacturing method of the present embodiment, the following effects (1) to (3) can be attained.

(1) Water Resistance and Oxidation Resistance can be improved:

By performing the heat treatment (annealing process), Mn elements in the CuMn alloy layer 24 react with Si elements and O elements in the insulating film 12-2 to form a uniform MnₓSi_{y}O_{z} film (barrier film) 19 of extremely thin film thickness (2 nm to 3 nm) on the interface in a self-alignment fashion.

It is confirmed that the MnₓSi_{y}O_{z} film (barrier film) 19 formed on the interface with the inter-level insulating film 12-2 by the heat treatment process is uniformly and continuously formed with an extremely thin film thickness of 2 nm to 3 nm. In this case, Cu is mainly used as a material in the conventional guard ring and a metal such as tantalum (Ta), which is a diffusion barrier insulating film, is used as the interface with the inter-level insulating film. Therefore, it is known that the water resistance and oxidation resistance of the guard ring are low since it permits water and oxygen gas to easily pass therethrough and corrodes Cu.

However, the MnₓSi_{y}O_{z} film, which is the barrier film 19 of the present embodiment, is an oxide and is no more oxidized. Further, since the barrier film is no more oxidized and is formed as a reaction-formed film which is continuously and densely formed, it does not permit water and oxygen gas to pass therethrough. Therefore, it is advantageous in that the film prevents corrosion of the Cu layer 17 and the water resistance and oxidation resistance of the guard ring can be enhanced and the reliability thereof can be enhanced.

(2) It is advantageous in Miniaturization:

As described above, the barrier film (MnₓSi_{y}O_{z} film) 19 is excellent in oxidation resistance and water resistance. Therefore, when the barrier film 19 is applied to the guard ring, it is possible to significantly reduce the number of layers of guard rings (for example, nine-layered guard rings) arranged on the peripheral portion of the conventional chip to half the number of layers of guard rings (for example, double-layered guard rings) or less.

Therefore, the occupied area of the guard ring in the semiconductor chip 10 can be reduced to half or less and it is advantageous in miniaturization.

(3) It is advantageous in Manufacturing Cost:

As described above, the barrier film 19 can be formed only by use of the heat treatment process without using a film formation process (for example, CVD method or the like).

When the barrier film 19 is formed, a CuMn alloy can be used as a target of the sputtering process. Therefore, the conventional manufacturing apparatus for the sputtering process can be applied as it is and the equipment investment is not necessary for new manufacturing equipment. Thus, it is advantageous in the manufacturing cost.

### SECOND EMBODIMENT

### Example in which Side Wall Barrier Film is Provided

Next, a semiconductor device according to a second embodiment of this invention is explained with reference to FIG. 7. FIG. 7 is a cross sectional view showing the semiconductor device according to the present embodiment. The present embodiment relates to a case wherein a side wall barrier film is provided on the side surface of the semiconductor chip which lies outside the guard rings at the time of dicing. In this explanation, the explanation for portions which are the same as those of the first embodiment is omitted.

In the first embodiment, an example in which the barrier film 19 is applied to the guard rings GR1, GR2 is explained. If the guard ring having the barrier film 19 is provided, it is considered that one guard ring is sufficient. If two or more guard rings are provided in time of need, it can be made more stable from the viewpoint of the oxidation resistance and water resistance. However, in this case, as the number of guard rings is increased, the occupied area becomes larger and it becomes disadvantageous in miniaturization.

Therefore, the present embodiment is made to avoid the disadvantage that the occupied area is increased. As shown in FIG. 7, a dicing groove 29 which penetrates through the inter-level insulating films 12-1, 12-2, 14-1, 14-2 is formed for dicing outside the guard rings of the semiconductor chip. The present embodiment is different from the first embodiment in that a side wall barrier film (MnₓSi_{y}O_{z} film) 30 is formed on the side wall and the bottom surface of the dicing groove 29.

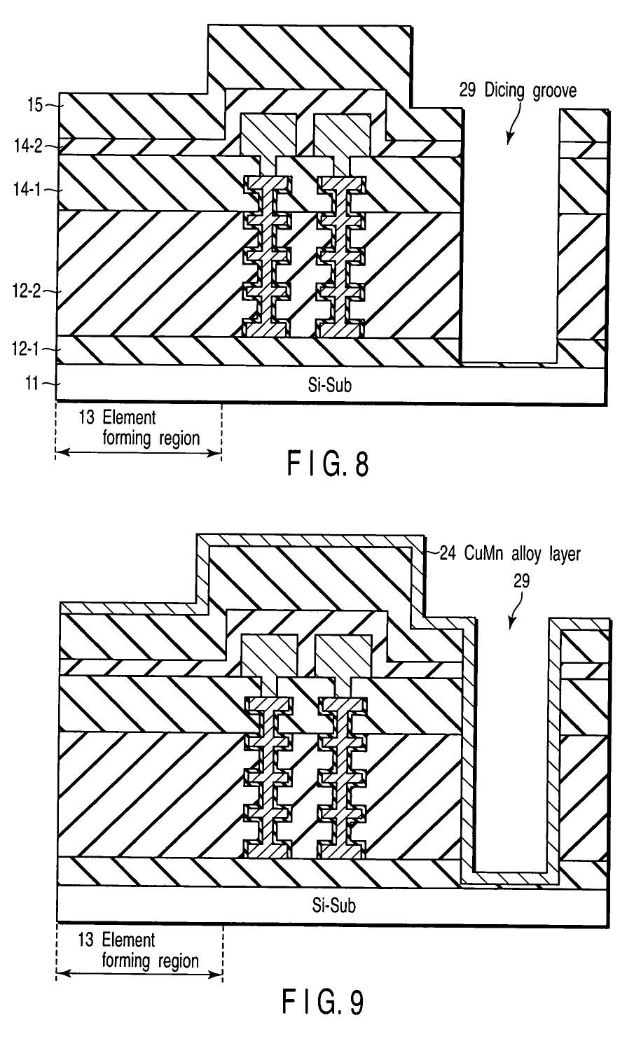

Next, the manufacturing method of the semiconductor device according to the present embodiment is explained with reference to FIGS. 8 to 10 by taking the semiconductor device shown in FIG. 7 as an example.

First, as shown in FIG. 8, a silicon wafer subjected to a multilayered wiring process after guard rings are formed by the same manufacturing process as that of the first embodiment is divided by dicing so that the divided silicon wafers will be incorporated into respective packages. At the time of the dicing process, cracks (film breakage) or film separation occurs due to dicing in some cases. The phenomenon often occurs, particularly, when the inter-level insulating films 12-1, 12-2, 14-1, 14-2 are formed of a low dielectric constant insulating film (SiOC film), porous SiOC film or the like.

Therefore, it is advantageous to previously eliminate the passivation film 15 and inter-level insulating films 14-2, 14-1, 12-1, 12-2 before the dicing process from the viewpoint of preventing occurrence of cracks. That is, for example, a dicing groove 29 which penetrates through the passivation film 15 and inter-level insulating films 14-2, 14-1, 12-1, 12-2 is formed to substantially reach the upper surface of the silicon substrate 11 by an anisotropic etching process such as the RIE process. In this case, the inter-level insulating films 12-1, 12-2, 14-1, 14-2 containing O (oxygen) are exposed to the side surface of the dicing groove 29 formed by removing a large portion thereof in the etching process.

Next, as shown in FIG. 9, for example, a CuMn layer 24 is deposited on the passivation film 15 and the side wall and bottom surface of the dicing groove 29 by use of the sputtering method or the like.

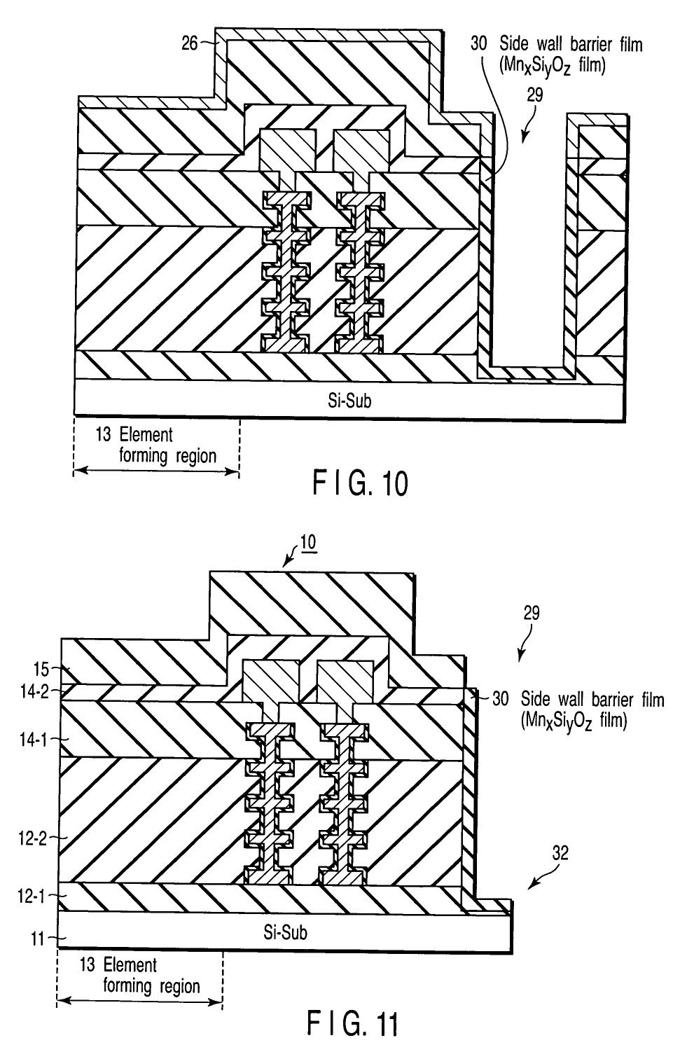

Then, as shown in FIG. 10, for example, the heat treatment (annealing process) is performed for 30 min to 60 min at temperatures of 200° C. to 600° C. to react Mn elements in the CuMn alloy layer 24 with Si elements and O elements in the insulating layers 14-2, 14-1, 12-2, 12-1 and form a uniform MnₓSi_{y}O_{z} film (side wall barrier film) 30 with extremely thin film thickness (2 nm to 3 nm) on the interface in a self-alignment fashion.

The reason why the MnₓSi_{y}O_{z} film (side wall barrier film) 30 is formed in a self-alignment fashion on the interface with the insulating layers 14-2, 14-1, 12-2, 12-1 is that Si elements and O elements which are required for formation of the MnₓSi_{y}O_{z} film 30 are supplied from the inter-level insulating films.

The semiconductor device shown in FIG. 7 is manufactured by the above manufacturing method.

As described above, according to the configuration and manufacturing method of the present embodiment, the same effects as the effects (1) to (3) explained in the first embodiment can be attained.

Further, in the present embodiment, the side wall barrier film (MnₓSi_{y}O_{z} film) 30 is formed on the side wall and bottom surface of the dicing groove 29.

Therefore, penetration of oxygen gas and water from the dicing groove 29 side into the semiconductor chip 10 can be prevented. Thus, penetration of oxygen gas and water from the side wall side of the semiconductor chip 10 can be prevented before using the guard rings GR1, GR2. Therefore, the guard rings GR1, GR2 lying inside the side wall can be omitted and even if they are arranged, the number of guard rings can be set small. As a result, an increase in the occupied area due to an increase in the number of guard rings can be suppressed and it is advantageous in miniaturization.

[Modification 1 (Example in which Side Wall Barrier Film is provided)

Next, a semiconductor device according to a modification 1 of this invention is explained with reference to FIG. 11. FIG. 11 is a cross sectional view showing the semiconductor device according to the modification 1. The modification 1 relates to a case wherein a side wall barrier film is further provided on the side surface of a semiconductor chip which lies outside the guard rings at the time of dicing. In this explanation, the explanation for portions which are the same as those of the second embodiment is omitted.

As shown in FIG. 11, a silicon wafer is divided by dicing after forming the side wall barrier film 30 so that the divided silicon wafers will be incorporated into respective packages. Thus, the modification 1 is different from the second embodiment in that the side wall barrier film 30, inter-level insulating film 12-1 and silicon substrate 11 are separated in a portion 32 of the dicing groove 29.

At the time of the dicing process for separation in the portion 32, penetration of oxygen gas and water from the groove 29 can be prevented since the side wall barrier film 30 is provided. Therefore, occurrence of cracks (film breakage) or separation of the film in the inter-level insulating films 12-1, 12-2, 14-1, 14-2 at the time of the dicing process can be prevented and the reliability can be enhanced.

[Modification 2 (Example in which Side Wall Barrier Film is provided)]

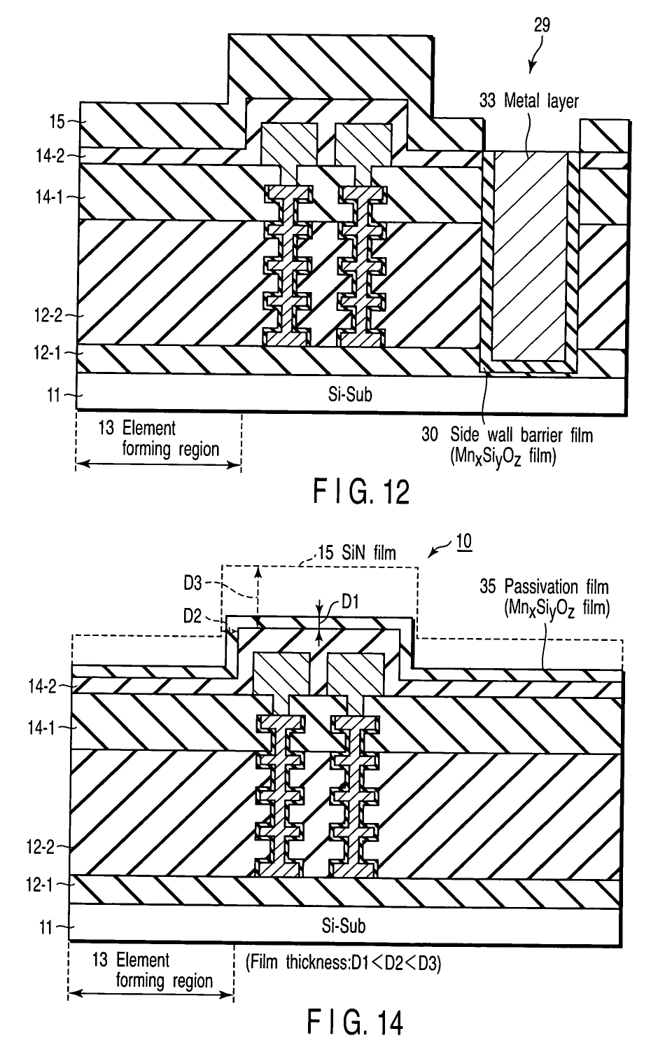

Next, a semiconductor device according to a modification 2 of this invention is explained with reference to FIG. 12. FIG. 12 is a cross sectional view showing the semiconductor device according to the modification 2. The modification 2 relates to a case wherein a side wall barrier film is further provided on the side surface of a semiconductor chip which lies outside the guard rings at the time of dicing. In this explanation, the explanation for portions which are the same as those of the second embodiment is omitted.

As shown in FIG. 12, a side wall barrier film 30 is formed on the side wall and bottom surface of a dicing groove 29. The modification 2 is different from the second embodiment in that a metal layer 33 is provided on the side wall barrier film 30 to fill the dicing groove 29. The metal layer 33 is formed of a metal such as Cu or Al, for example.

In the manufacturing method, the side wall barrier film 30 is formed along the groove by the manufacturing process which is the same as that of the second embodiment. Then, a Cu layer is deposited on the side wall barrier film 30 by the sputtering method or the like and filled in the groove 29 to manufacture the semiconductor device shown in FIG. 12.

As described above, according to the configuration and manufacturing method of the modification 2, the same effect as that of the second embodiment can be attained.

Further, according to the modification 2, the metal layer 33 is formed on the side wall barrier film 30 to fill the dicing groove 29. Therefore, the mechanical strength of the groove 29 portion can be increased to prevent occurrence of cracks (film breakage) or film separation in the inter-level insulating films 12-1, 12-2, 14-1, 14-2 and the reliability can be enhanced.

[Modification 3 (Example in which Crack Prevention Groove is provided)]

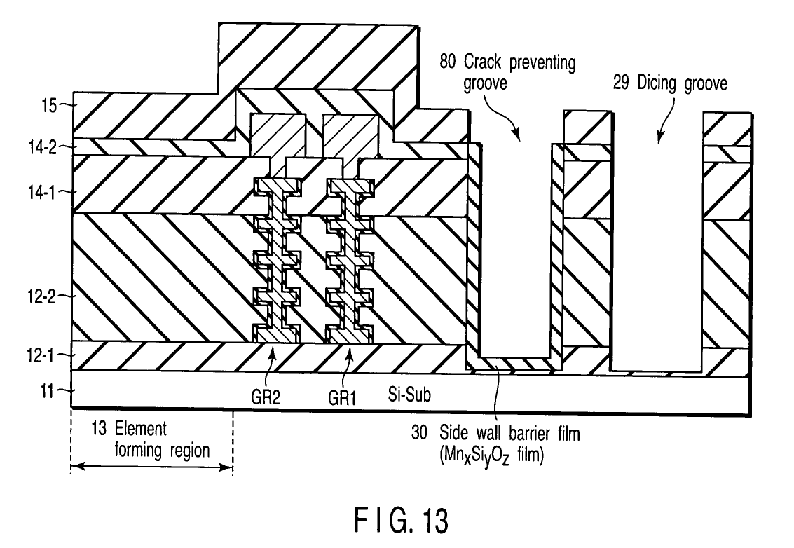

Next, a semiconductor device according to a modification 3 of this invention is explained with reference to FIG. 13. FIG. 13 is a cross sectional view showing the semiconductor device according to the modification 3. The modification 3 relates to a case wherein a crack prevention groove is further provided between the guard rings and a dicing groove on the dicing line. In this explanation, the explanation for portions which are the same as those of the second embodiment is omitted.

As shown in FIG. 13, the semiconductor device according to the present modification is different from that of the second embodiment in the following points. That is, a crack prevention groove 80 which penetrates through the passivation film 15 and inter-level insulating films 14-2, 14-1, 12-2 and has a bottom portion in the inter-level insulating film 12-1 is formed between the guard rings GR1, GR2 and the dicing groove 29 on the dicing line.

Further, a side wall barrier film (MnₓSi_{y}O_{z} film) 30 is provided on the side wall and bottom surface of the crack prevention groove 80. The manufacturing method is substantially the same as that of the second embodiment, and therefore, a detailed explanation thereof is omitted.

As described above, according to the configuration and manufacturing method of the modification 3, the same effect as that of the second embodiment can be attained.

Further, the crack prevention groove 80 which penetrates through the passivation film 15 and inter-level insulating films 14-2, 14-1, 12-2 and has the bottom portion in the inter-level insulating film 12-1 is formed between the guard rings GR1, GR2 and the dicing groove 29 on the dicing line.

Therefore, it is advantageous in that even if cracks occur from the dicing groove 29 side, the cracks can be prevented from extending to the element forming region 13 side by the presence of the groove 80.

Further, the side wall barrier film (MnₓSi_{y}O_{z} film) 30 is provided on the side wall and bottom surface of the crack prevention groove 80.

Therefore, penetration of oxidizing gas and water from the crack prevention groove 80 can be prevented and the reliability can be enhanced.

Even if the dicing groove 29 shown in FIG. 13 is not formed on the dicing line, the cracks can be prevented from extending to the element forming region 13 by the presence of the groove 80. The mechanical strength can be further enhanced by embedding a metal layer or the like into the groove 80.

### THIRD EMBODIMENT

### Example of Passivation Film

Next, a semiconductor device according to a third embodiment of this invention is explained with reference to FIG. 14. The present embodiment relates to a passivation film which is formed to cover the surface of a semiconductor chip 10. In this explanation, the explanation for portions which are the same as those of the first embodiment is omitted.

As shown in FIG. 14, the present embodiment is different from the first embodiment in that a passivation film (MnₓSi_{y}O_{z} film) 35 is formed on the inter-level insulating film 14-2 to cover the surface of the semiconductor chip 10. Broken lines 15 in FIG. 14 indicate a case wherein an SiN film 15 is formed as the passivation film on the inter-level insulating film 14-2 by use of the plasma CVD method.

In the manufacturing method, first, a CuMn alloy layer is deposited on the inter-level insulating film 14-2 by use of the sputtering method, for example.

Then, the heat treatment (annealing process) is performed for 30 min to 60 min at temperatures of 200° C. to 600° C. while the CuMn alloy layer is kept set in contact with the inter-level insulating layer 14-2. By the heat treatment, Mn elements in the CuMn alloy layer react with Si elements and O elements in the inter-level insulating layer 14-2 to form a uniform and extremely thin (2 nm to 3 nm) MnₓSi_{y}O_{z} film (passivation film) 35 in a self-alignment fashion on the interface. By the above manufacturing method, the semiconductor device shown in FIG. 14 is manufactured.

As described above, according to the configuration and manufacturing method of the present embodiment, the same effects as the effects (1) to (3) explained in the first embodiment can be attained.

Further, in the present embodiment, the passivation film (MnₓSi_{y}O_{z} film) 35 is formed on the inter-level insulating film 14-2 to cover the surface of the semiconductor chip 10.

The broken lines 15 indicate a case wherein the SiN film 15 is formed as the passivation film on the inter-level insulating film 14-2 by use of the plasma CVD method. However, in order to prevent penetration of water and oxygen by use of the SiN film 15, it is necessary to set the film thickness D3 thereof to 600 nm or more. At this time, the film thickness D2 of the side wall portion is made extremely small. Therefore, the manufacturing cost becomes high and miniaturization is prevented. Particularly, when multilayered wirings having large step differences are arranged in a DRAM (Dynamic Random Access Memory) or the like, it is necessary to further increase the film thickness D3 of the SiN film 15.

However, the film thickness D1 of the passivation film (MnₓSi_{y}O_{z} film) 35 in this example is an extremely thin film of 2 nm to 3 nm (film thickness: D1<D2<D3) as described above. Further, the film is excellent in the oxidation resistance and water resistance. As a result, since the occupied area of the SiN film 15 can be omitted, it is advantageous in miniaturization.

Further, since the film thickness D1 is extremely small, the etching time required for forming an opening for a pad can be reduced when the pad which penetrates through the passivation film 35 and inter-level insulating film 14-2 is formed. Therefore, an advantage in the manufacturing process that the etching cost can be lowered can be attained.

Further, the passivation film (MnₓSi_{y}O_{z} film) 35 can be formed with the uniform film thickness D1 on the side wall portion having a large step difference. Therefore, it is advantageous in that the film can be applied to various devices such as a DRAM at low cost.

[Modification 4 (Example in which Passivation Film is provided between Layers)]

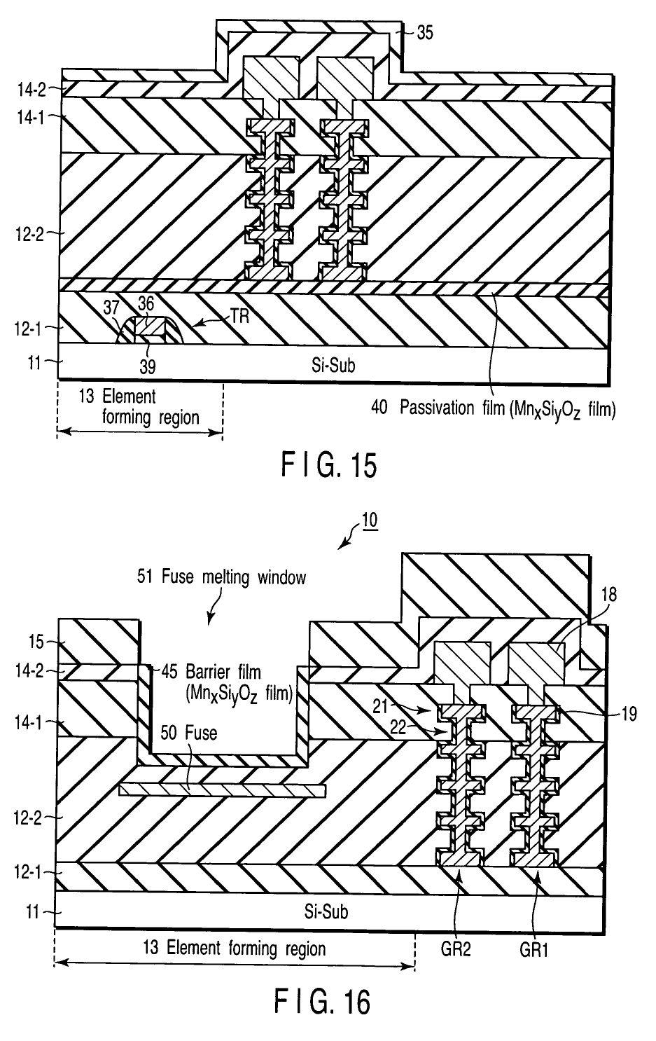

Next, a semiconductor device according to a modification 4 of this invention is explained with reference to FIG. 15. FIG. 15 is a cross sectional view showing the semiconductor device according to the modification 4. The modification 4 relates to a case wherein the passivation film is formed between layers. In this explanation, the explanation for portions which are the same as those of the third embodiment is omitted.

As shown in FIG. 15, a transistor TR is formed on the silicon substrate 11 as one example of the element structure. The transistor TR includes a gate insulating film 39 formed on the substrate 11, a gate electrode 36 formed on the gate insulating film 39, spacers 37 formed on the side walls of the gate electrode 36 and source and drain regions separately formed in the substrate 11 to sandwich the gate electrode 36.

An inter-level insulating film 12-1 is formed to cover the element structure such as the transistor.

The present modification is different from the third embodiment in that a passivation film (MnₓSi_{y}O_{z} film) 40 is formed between the inter-level insulating films 12-1 and 12-2.

In the manufacturing method, after the element structure such as the transistor is formed on the silicon substrate 11 by a known manufacturing process, an SiO₂ film is deposited to cover the transistor TR and the like by use of the CVD method and thus an inter-level insulating film 12-1 is formed.

Next, a CuMN alloy layer is deposited on the inter-level insulating film 12-1 by use of the sputtering method, for example.

Then, the heat treatment (annealing process) is performed for 30 min to 60 min at temperatures of 200° C. to 600° C. while the CuMn alloy layer 32 is kept set in contact with the inter-level insulating layer 12-1. By the heat treatment, Mn elements in the CuMn alloy layer react with Si elements and O elements in the inter-level insulating layer 12-1 to form a uniform and extremely thin (2 nm to 3 nm) MnₓSi_{y}O_{z} film (passivation film) 40 on the interface in a self-alignment fashion. After this, the semiconductor device shown in FIG. 15 is manufactured by the manufacturing method which is the same as that of the third embodiment.

As described above, according to the configuration and manufacturing method of the present embodiment, the same effects as the effects (1) to (3) explained in the first embodiment can be attained.

Further, the passivation film (MnₓSi_{y}O_{z} film) 40 is formed between the inter-level insulating films 12-1 and 12-2.

Thus, by forming the passivation film 40 between the transistor TR and the wiring layer, penetration of water caused by a material used in the LSI and impurity which deteriorates the performance of the transistor can be prevented. As a result, it is confirmed that the reliability of the transistor TR can be markedly enhanced.

The passivation film 40 formed between the layers is not always necessarily formed between the element structure such as the transistor TR and the inter-level insulating film 12-1, but also it can be formed between multilayered wiring layers. In this case, it is advantageous in that penetration of oxidizing gas and water into the multilayered wiring layer is prevented and the oxidation resistance and water resistance of the multilayered wiring layer can be enhanced.

### FOURTH EMBODIMENT

### Example in which Fuse is Provided

Next, a semiconductor device according to a fourth embodiment of this invention is explained with reference to FIG. 16. FIG. 16 is a cross sectional view showing the semiconductor device according to the present embodiment. The present embodiment relates to a semiconductor device having a fuse. In this explanation, the explanation for portions which are the same as those of the first embodiment is omitted.

As shown in FIG. 16, the semiconductor device according to the present embodiment is different from that of the first embodiment in the following points.

That is, a fuse 50 is formed in an inter-level insulating film 12-2. For example, the fuse 50 is formed of a metal containing Cu as a main component.

In order to melt the fuse 50, a fuse melting window 51 formed by removing portions of a passivation film 15 and inter-level insulating films 14-1, 14-2 which lie above the fuse 50 is provided. The fuse melting window 51 is provided to easily melt (blow) the fuse 50 by applying laser light thereto.

A barrier film (MnₓSi_{y}O_{z} film) 45 is formed on the side walls and bottom surfaces of the inter-level insulating films 14-1, 14-2 which are exposed to the fuse melting window 51.

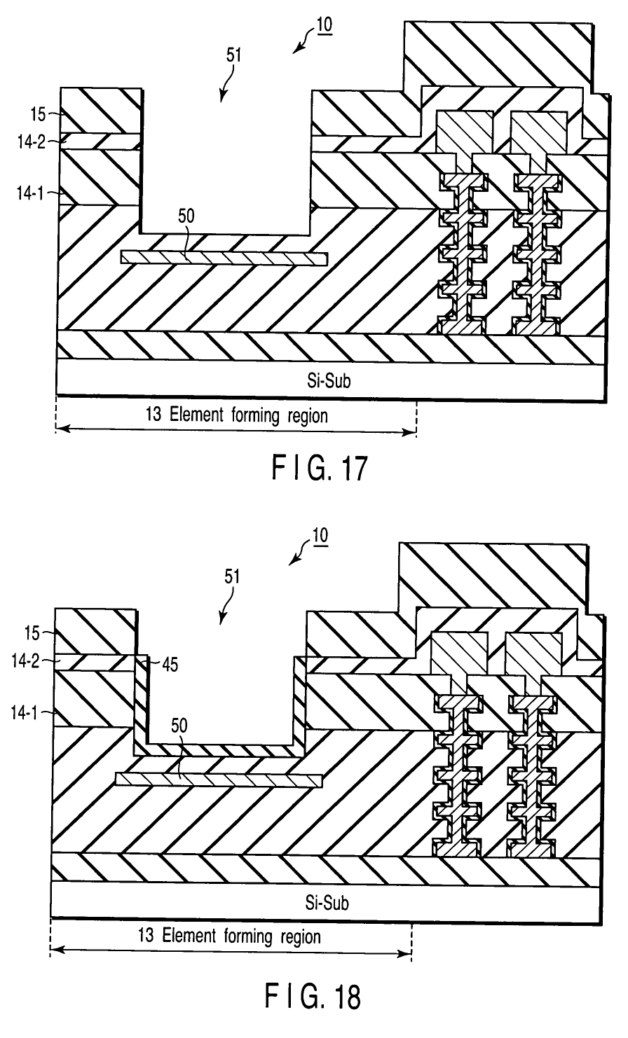

Next, the manufacturing method of the semiconductor device according to the present embodiment is explained with reference to FIGS. 17 and 18 by taking the semiconductor device shown in FIG. 16 as an example.

First, as shown in FIG. 17, a semiconductor chip 10 is formed by the same process as described above. Then, portions of the passivation film 15 and inter-level insulating films 14-1, 14-2 which lie above the fuse 50 are removed by use of an anisotropic etching process such as the RIE method to form a fuse melting window 51 to which the upper surface of the inter-level insulating film 12-2 is exposed.

After this, as shown in FIG. 18, a CuMn alloy layer is deposited to a thickness of 10 nm to 30 nm on the side walls of the inter-level insulating films 14-2, 14-1 and the inter-level insulating film 12-2 which are exposed by forming the melting window 51 by use of the sputtering method, for example.

Next, the heat treatment (annealing process) is performed for 30 min to 60 min at temperatures of 200° C. to 600° C. while the CuMn alloy layer is kept set in contact with the inter-level insulating layers 14-1, 14-2, 12-1. By the heat treatment, Mn elements in the CuMn alloy layer react with Si elements and O elements in the inter-level insulating layers 14-1, 14-2, 12-1 to form a uniform and extremely thin (2 nm to 3 nm) MnₓSi_{y}O_{z} film (barrier film) 45 on the interface in a self-alignment fashion. Thus, the semiconductor device shown in FIG. 16 is manufactured by the above manufacturing method.

As described above, according to the configuration and manufacturing method of the present embodiment, the same effects as the effects (1) to (3) explained in the first embodiment can be attained.

Further, the barrier film (MnₓSi_{y}O_{z} film) 45 is formed on the side walls and bottom surfaces of the inter-level insulating films 14-1 and 14-2 which are exposed to the fuse melting window 51.

Therefore, penetration of oxidizing gas and water from the fuse melting window 51 can be prevented and corrosion of the fuse 50 can be prevented. As a result, according to the semiconductor device having the barrier film 45 formed therein, for example, a problem such as corrosion of the fuse 50 does not occur even if the semiconductor device is left as it is for 10 years which is the guarantee period of the product such as the LSI.

The fuse 50 is not necessarily formed in the inter-level insulating film 12-2 and can be formed in various other layers. For example, GC (Gate conductor) and Cu wirings are representative examples. Therefore, the fuse melting window 51 and barrier film 45 can be provided in adequately selected locations and the location in which the fuse is formed is not limited to the position shown in the present embodiment.

### FIFTH EMBODIMENT

### Example in which Melted Fuse is Provided

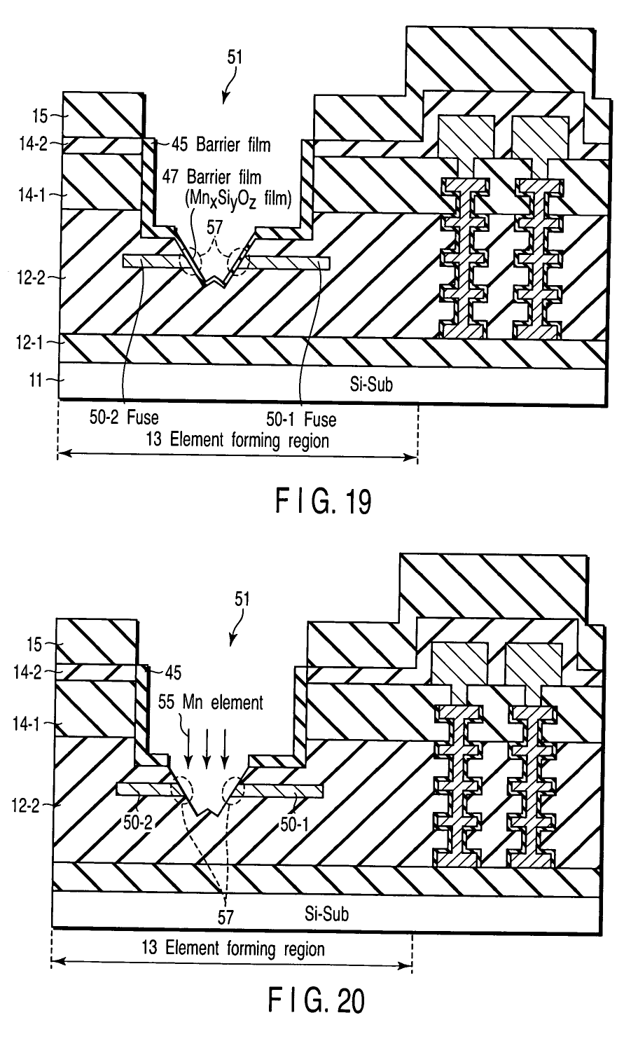

Next, a semiconductor device according to a fifth embodiment of this invention is explained with reference to FIG. 19. FIG. 19 is a cross sectional view showing the semiconductor device according to the present embodiment. The present embodiment relates to a semiconductor device having a melted fuse. In this explanation, the explanation for portions which are the same as those of the fourth embodiment is omitted.

As shown in FIG. 19, in the semiconductor device according to the present embodiment, melted and separated fuses 50-1, 50-2 are provided in an inter-level insulating film 12-2. The present embodiment is different from the fourth embodiment in that a barrier film (MnₓSi_{y}O_{z} film) 47, which is continuously connected to a barrier film 45, is formed on the inter-level insulating film 12-2 and end portions 57 of the fuses 50-1, 50-2 which are exposed when the fuse is melted.

Next, the manufacturing method of the semiconductor device according to the present embodiment is explained with reference to FIGS. 20 to 22 by taking the semiconductor device shown in FIG. 19 as an example.

First, as shown in FIG. 20, laser light is applied to a desired fuse through the fuse melting window 51 to melt (blow) the fuse via the barrier film 45 and inter-level insulating film 12-1.

Then, Mn atoms are ionized, accelerated and implanted by use of an ion-implantation process, for example, onto the end portions 57 of the fuses 50-1, 50-2 and the surface of the inter-level insulating film 12-2 exposed by the melting process.

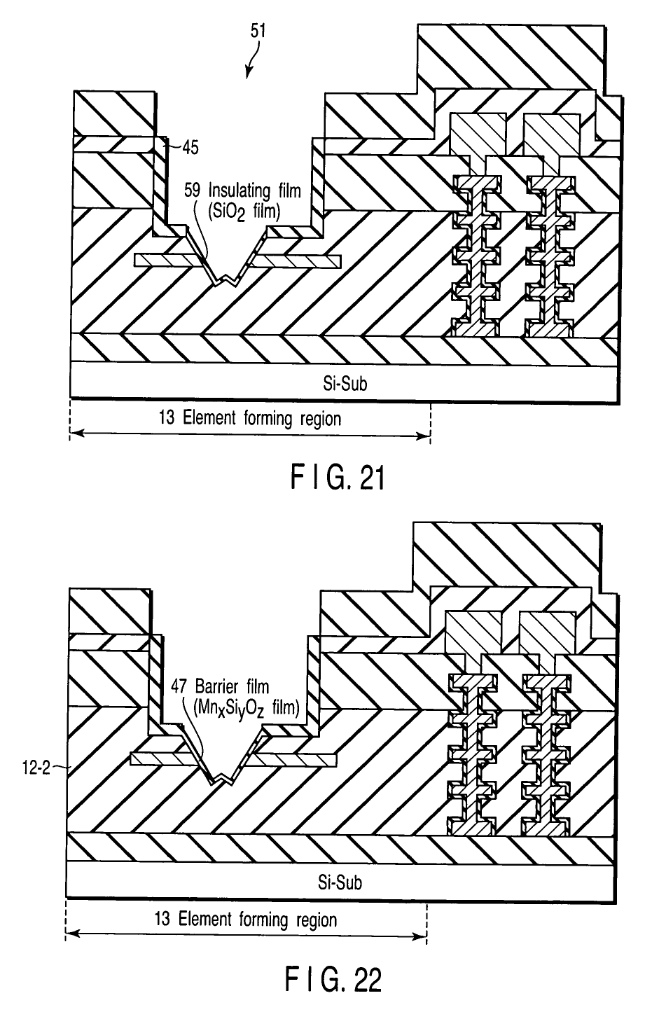

After this, as shown in FIG. 21, an insulating film (SiOₓ film, SiOC film or the like) 59, which is a liquid, is coated on the end portions 57 of the fuses 50-1, 50-2 and the surface of the inter-level insulating film 12-2 exposed and is embedded in the window 51 obtained after fuse melting.

Then, a CuMn alloy layer is deposited to a thickness of approximately 10 nm to 30 nm on the insulating film 59 by use of the sputtering method, for example.

Next, as shown in FIG. 22, the heat treatment (annealing process) is performed for 30 min to 60 min at temperatures of 200° C. to 600° C. while the CuMn alloy layer is kept set in contact with the inter-level insulating layer 12-2 and the coated insulating film 59. By the heat treatment, Mn elements in the CuMn alloy layer react with Si elements and O elements in the inter-level insulating layer 12-2 and coated insulating film 59 to form a uniform and extremely thin (2 nm to 3 nm) MnₓSi_{y}O_{z} film (barrier film) 47 on the interfaces in a self-alignment fashion. Thus, the semiconductor device shown in FIG. 19 is manufactured by the above manufacturing method.

As described above, according to the configuration and manufacturing method of the present embodiment, the same effects as the effects (1) to (3) explained in the first embodiment can be attained.

Further, as described above, Mn atoms are ionized, accelerated and implanted by use of the ion-implantation process, for example, onto the end portions 57 of the fuses 50-1, 50-2 exposed by the melting process. After this, the insulating film 59, which is a liquid, is coated on the exposed end portions 57 of the fuses 50-1, 50-2 and then the heat treatment process is performed.

Therefore, the barrier film 47 can be formed not only on the exposed inter-level insulating film 12-2 but also on the exposed end portions 57 of the fuses 50-1, 50-2. Thus, the MnₓSi_{y}O_{z} film (barrier film) 47 can be formed to cover the entire surface of the complicated cross section after fuse blowing. Further, the barrier film 47 is continuously connected to the barrier film 45 which is formed on the bottom portion of the fuse melting window 51.

As a result, even after fuse melting, penetration of oxidation gas and water from the exposed portion after fuse blowing can be prevented and oxidation and corrosion of the separated fuses 50-1, 50-2 can be prevented. Further, the barrier film 47 is formed on a portion other than the end portions 57 of the fuses 50-1, 50-2, that is, on a portion of the inter-level insulating film 12-2 exposed by the melting process. In this case, however, since the barrier film 47 is an insulating film, no problem relating to the electrical characteristic of the device occurs.

As indicated in the fourth embodiment, penetration of water and oxidizing gas from the fuse melting window 51 can be prevented by forming the barrier film 47 on the side wall and bottom surface of the fuse melting window 51 and oxidation of the fuse 50 itself and an extension of the wiring can be prevented. Further, as indicated in the fifth embodiment, oxidation can be substantially completely prevented from proceeding from the exposed portion after fuse blowing by forming the barrier film 47 on the exposed portion after fuse blowing. Therefore, the fuses 50-1, 50-2 which are separated after fuse melting can maintain the stable state after fuse blowing.

### SIXTH EMBODIMENT

### Example Applied to Pad Portion

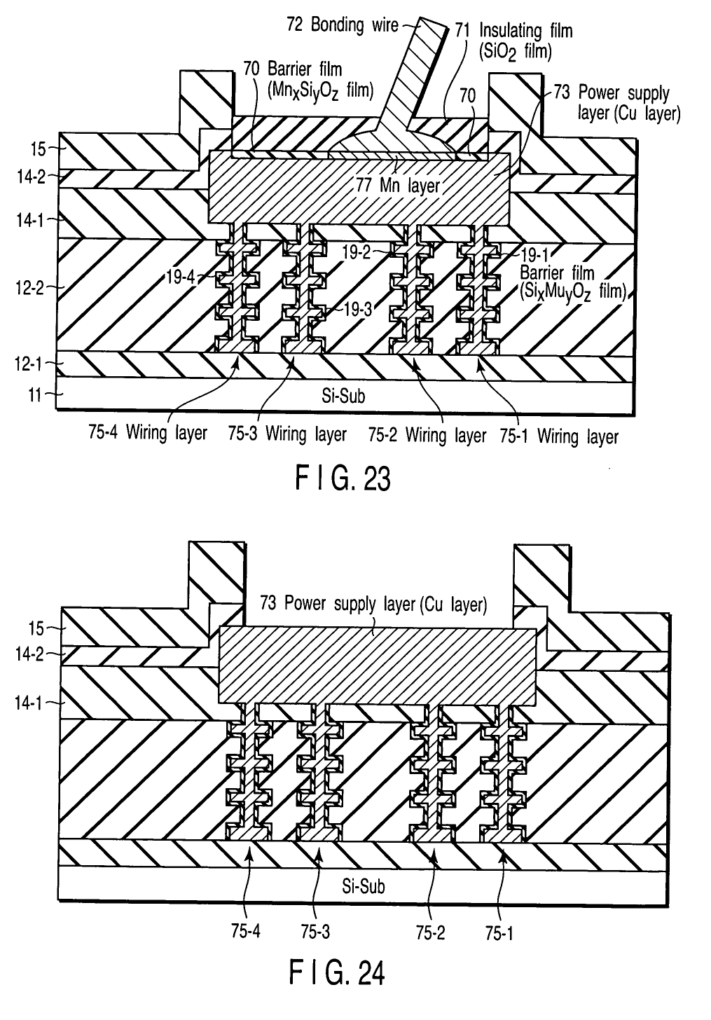

Next, a semiconductor device according to a sixth embodiment of this invention is explained with reference to FIG. 23. The present embodiment relates to an example in which the barrier film (MnₓSi_{y}O_{z} film) explained in the first embodiment is applied to a pad portion bonded. In this explanation, the explanation for portions which are the same as those of the first embodiment is omitted.

As shown in FIG. 23, the semiconductor device according to the present embodiment is different from that of the first embodiment in the following points.

A plurality of wiring layers 75-1 to 75-4 containing Cu as a main component are provided in an inter-level insulating film 12-2 and a power supply layer 73 electrically connected to the wiring layers 75-1 to 75-4 and containing Cu as a main component are provided in inter-level insulating films 14-1, 14-2.

Further, a bonding wire 72, which is used to supply power supply voltage to the power supply line 73 is formed on the power supply line 73 and an insulating layer 71 is formed to cover the bonding wirer 72 and power supply layer 73. For example, the insulating layer 71 is formed of a coating type SiO₂ film or the like.

An Mn layer 77 is formed on the interface between the bonding wire 72 and the power supply layer 73 and a barrier film (MnₓSi_{y}O_{z} film) 70 is formed on the interface between the insulating film 71 and the power supply layer 73.

Next, the manufacturing method of the semiconductor device according to the present embodiment is explained with reference to FIGS. 24 to 28 by taking the semiconductor device shown in FIG. 23 as an example.

First, as shown in FIG. 24, wiring layers 75-1 to 75-4, inter-level insulating films 14-1, 14-2, passivation film 15 and power supply layer 73 are formed by use of a known manufacturing process.

Then, for example, the anisotropic etching process such as the RIE method is performed to remove a portion up to the surface of the power supply layer 73 to form an opening which penetrates through the passivation film 15 and inter-level insulating film 14-2 and exposes the surface of the power supply layer 73.

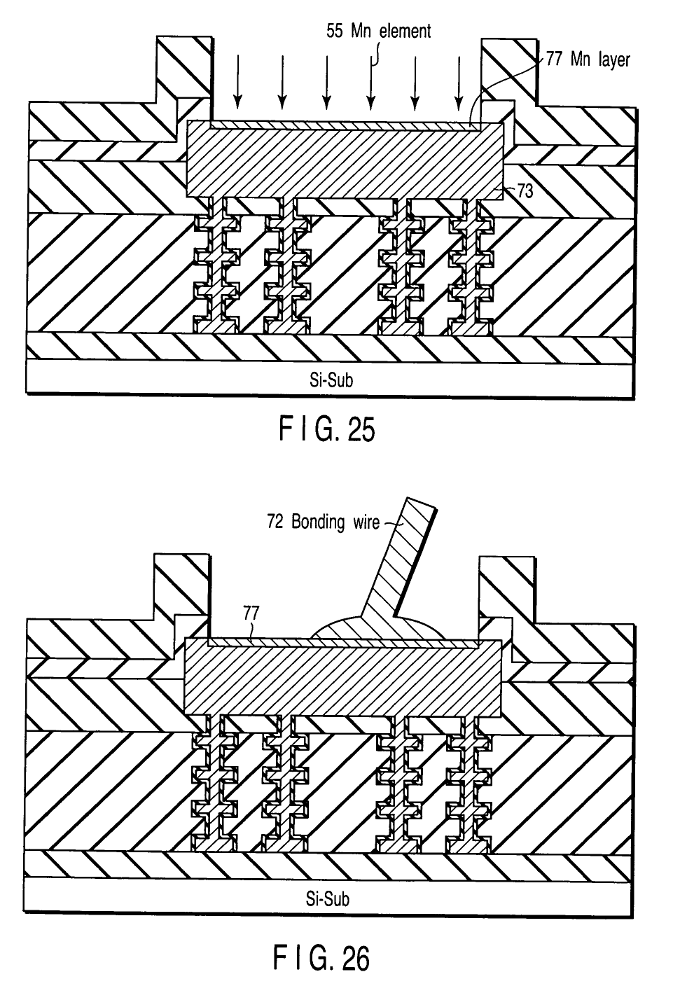

After this, as shown in FIG. 25, for example, Mn elements 55 are implanted into the power supply layer 73 by use of the ion-implantation process to form an Mn layer 77 in the surface area of the power supply layer 73.

At the time of the ion-implantation process, it is preferable to control and set the Mn concentration in the Mn layer 77 equal to or lower than 1 at %. This is because the resistance of the pad portion in which the rising rate in the resistivity of the power supply layer (Cu layer) 73 is 2.8 μohm cm/Mn at % is low when the Mn elements 55 are implanted into the power supply layer 73 and no problem occurs from the viewpoint of the resistance in the above range.

After this, as shown in FIG. 26, a bonding wire 72 is formed on the Mn layer 77 by use of a bonding process.

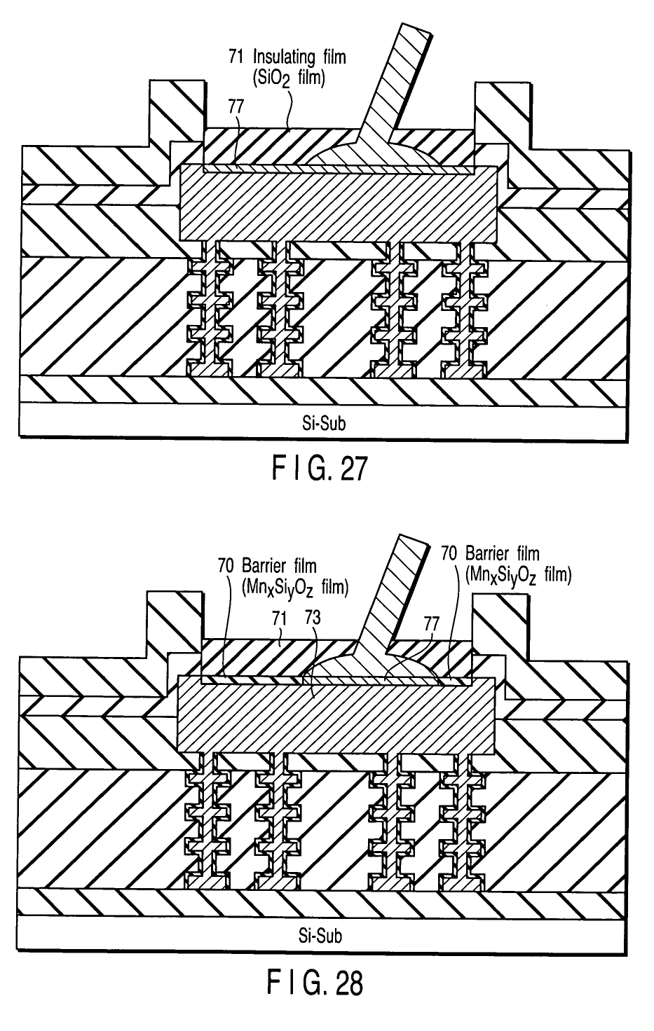

Then, as shown in FIG. 27, a coating type SiO₂ film or SiOC film is coated on the exposed surface portion of the Mn layer 77 which is not connected to the bonding wire 72 to cover the power supply layer 73 so as to form an insulating layer 71.

Next, as shown in FIG. 28, the heat treatment is performed with respect to the coated insulating layer 71 for 30 min to 60 min at temperatures of 200° C. to 400° C., for example, to harden the insulating layer 71.

While the heat treatment process is being performed, Mn elements in the Mn layer 77 react with Si elements and O elements in the insulating layer 71 to form a uniform and extremely thin (2 nm to 3 nm) MnₓSi_{y}O_{z} film (barrier film) 70 in a self-alignment fashion on the interface between the insulating layer 71 and the power supply layer 73. Thus, the semiconductor device shown in FIG. 23 is manufactured by the above manufacturing method.

As described above, according to the configuration and manufacturing method of the present embodiment, the same effects as the effects (1) to (3) explained in the first embodiment can be attained.

Further, the barrier film (MnₓSi_{y}O_{z} film) 70 is formed on the interface between the insulating layer 71 and the power supply layer 73.

Therefore, the surface of the power supply layer (Cu layer) 73 which is less resistant to oxidation is not exposed and when the LSI is used for a long period of time, occurrence of a problem relating to the oxidation resistance and water resistance can be prevented.

Conventionally, an aluminum layer is generally formed on the power supply layer 73, but since the barrier film 70 is formed in the semiconductor device of the present embodiment, it is not necessary to form the aluminum layer. Therefore, since a film formation process for forming the aluminum layer, lithography process and etching process and a manufacturing device therefor can be omitted, the manufacturing cost can be significantly reduced.

Further, the heat treatment process for forming the barrier film 70 can also be used as a heat treatment process for hardening the coated insulating film 71. In this respect, the manufacturing cost can be lowered.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a guard ring formed in an inter-level insulating film on a semiconductor substrate to surround an element forming region on the semiconductor substrate and containing Cu as a main component, and
a first barrier film formed on an interface between the inter-level insulating film and the guard ring and containing a compound of a preset metal element and a constituent element of the inter-level insulating film as a main component.

2. The semiconductor device according to claim 1, wherein the guard ring has a multilayered wiring structure which includes a wiring layer formed in the inter-level insulating film and a contact plug linked with and electrically connected to the wiring layer.

3. The semiconductor device according to claim 1, further comprising a first groove which is formed to surround the element forming region outside the guard ring and penetrate through the inter-level insulating film to a portion near the surface of the semiconductor substrate.

4. The semiconductor device according to claim 3, further comprising a second barrier film formed along an inner wall of the first groove and containing a compound of a preset metal element and a constituent element of the inter-level insulating film as a main component.

5. The semiconductor device according to claim 3, wherein a bottom portion of the first groove is separated from the semiconductor substrate.

6. The semiconductor device according to claim 3, further comprising a metal layer formed to fill the first groove.

7. The semiconductor device according to claim 3, further comprising a second groove which is formed to surround the element forming region outside the first groove and penetrate through the inter-level insulating film to a portion near the surface of the semiconductor substrate.

8. The semiconductor device according to claim 4, wherein the preset metal element contains at least one element selected from a group consisting of Mn, Nb, Zr, Cr, V, Y, Tc and Re, the constituent element contains O and at least one element selected from a group consisting of Si, C and F, and the first and second barrier films contain a material selected from a group consisting of αₓO_{y}, αₓSi_{y}O_{z}, αₓC_{y}O_{z} and αₓF_{y}O_{z} as a main component, α indicating the preset metal element.

9. A semiconductor device comprising:
a fuse formed in an inter-level insulating film on a semiconductor substrate and containing Cu as a main component,
a fuse melting window formed in a portion of the inter-level insulating film which lies on the fuse to melt the fuse, and
a first barrier film formed on a side wall and bottom surface of the fuse melting window and containing a compound of a preset metal element and a constituent element of the inter-level insulating film as a main component.

10. The semiconductor device according to claim 9, further comprising a guard ring formed in the inter-level insulating film on the semiconductor substrate to surround an element forming region on the semiconductor substrate.

11. The semiconductor device according to claim 10, further comprising a second barrier film formed on an interface between the inter-level insulating film and the guard ring and containing a compound of a preset metal element and a constituent element of the inter-level insulating film as a main component.

12. The semiconductor device according to claim 10, wherein the guard ring has a multilayered wiring structure which includes a wiring layer formed in the inter-level insulating film and a contact plug linked with and electrically connected to the wiring layer.

13. The semiconductor device according to claim 11, wherein the preset metal element contains at least one element selected from a group consisting of Mn, Nb, Zr, Cr, V, Y, Tc and Re, the constituent element contains O and at least one element selected from a group consisting of Si, C and F, and the first and second barrier films contain a material selected from a group consisting of αₓO_{y}, αₓSi_{y}O_{z}, αₓC_{y}O_{z} and αₓF_{y}O_{z} as a main component, α indicating the preset metal element.

14. A semiconductor device comprising:
a power supply layer formed in an inter-level insulating film on a semiconductor substrate and containing Cu as a main component,
a bonding wire formed on the power supply layer,
an insulating film formed to cover the power supply layer and bonding wire, and
a first barrier film formed on an interface between the insulating film and the power supply layer and containing a compound of a preset metal element and a constituent element of the insulating film as a main component.

15. The semiconductor device according to claim 14, further comprising a metal layer formed on an interface between the power supply layer and the bonding wire and containing the preset metal element as a main component.

16. The semiconductor device according to claim 14, further comprising a multilayered wiring layer formed in the inter-level insulating film and electrically connected to the power supply layer.

17. The semiconductor device according to claim 14, further comprising a second barrier film formed on an interface between the inter-level insulating film and the multilayered wiring layer and containing a compound of a preset metal element and a constituent element of the inter-level insulating film as a main component.

18. The semiconductor device according to claim 17, wherein the preset metal element contains at least one element selected from a group consisting of Mn, Nb, Zr, Cr, V, Y, Tc and Re, the constituent element contains O and at least one element selected from a group consisting of Si, C and F, and the first and second barrier films contain a material selected from a group consisting of αₓO_{y}, αₓSi_{y}O_{z}, αₓC_{y}O_{z} and axFyOz as a main component, α indicating the preset metal element.
